(19) United States
(12) Patent Application Publication
(10) Pub. No.: US 2003/0038353 A1
(43) Pub. Date: Feb. 27, 2003

(54) Assemblies including stacked semiconductor devices separated by discrete conductive elements therebetween, packages including the assemblies, and methods

(76) Inventor: James M. Derderian, Boise, ID (US)

Correspondence Address: TRASK BRITT, P.O. BOX 2550, SALT LAKE CITY, UT, 84110, US

(21) Appl. No.: 09/938,106

(22) Filed: Aug. 23, 2001

(51) Int. Cl. H01L 23/02

(52) U.S. Cl. 257/685

(57) ABSTRACT

An assembly method that includes providing a first semiconductor device with discrete conductive elements protruding above a surface thereof and positioning a second semiconductor device at least partially over the first semiconductor device. A back side of the second semiconductor device rests upon at least some of the discrete conductive elements while remaining electrically isolated therefrom. The first and second semiconductor devices may be secured to one another with an adhesive material which is either placed on an active surface of the first semiconductor device before positioning the second semiconductor device thereover or introduced between the first and second semiconductor devices. Assemblies and packaged semiconductor devices that are formed in accordance with the method are also disclosed.

### BACKGROUND OF THE INVENTION

1. Field of the Invention

The present invention relates generally to semiconductor device assemblies, or so-called “multi-chip modules”, and, more specifically, to multi-chip modules in which two or more semiconductor devices are vertically stacked relative to one another. In particular, the present invention relates to semiconductor device assemblies in which the distances between adjacent stacked semiconductor devices are determined, at least in part, by the heights that discrete conductive elements, such as bond wires, tape-automated bond elements, or leads, protrude above an active surface of the lower of the adjacent, stacked semiconductor devices.

2. Background of Related Art

In order to conserve the amount of surface area, or “real estate”, consumed on a carrier substrate, such as a circuit board, by semiconductor devices connected thereto, various types of increased density packages have been developed. Among these various types of packages is the so-called “multi-chip module” (MCM). Some types of multi-chip modules include assemblies of semiconductor devices that are stacked one on top of another. The amount of surface area on a carrier substrate that may be saved by stacking semiconductor devices is readily apparent-a stack of semiconductor devices consumes roughly the same amount of real estate on a carrier substrate as a single, horizontally oriented semiconductor device or semiconductor device package.

Due to the disparity in processes that are used to form different types of semiconductor devices (e.g., the number and order of various process steps), the incorporation of different types of functionality into a single semiconductor device has proven very difficult to actually reduce to practice. Even in cases where semiconductor devices that carry out multiple functions can be fabricated, multi-chip modules that include semiconductor devices with differing functions (e.g., memory, processing capabilities, etc.) are often much more desirable since the separate semiconductor devices may be fabricated and assembled with one another much more quickly and cost-effectively (e.g., lower production costs due to higher volumes and lower failure rates).

Multi-chip modules may also contain a number of semiconductor devices that perform the same function, effectively combining the functionality of all of the semiconductor devices thereof into a single package.

An example of a conventional, stacked multi-chip module includes a carrier substrate, a first, larger semiconductor device secured to the carrier substrate, and a second, smaller semiconductor device positioned over and secured to the first semiconductor device. The second semiconductor device does not overlie bond pads of the first semiconductor device and, thus, the second semiconductor device does not cover bond wires that electrically connect bond pads of the first semiconductor device to corresponding contacts or terminals of the carrier substrate. As the bond pads of each lower semiconductor device are not covered by the next higher semiconductor device, spacing between the semiconductor devices is not important. Thus, any suitable adhesive may be used to secure the semiconductor devices to one another. Such a multi-chip module is disclosed and illustrated in U.S. Pat. No. 6,212,767, issued to Tandy on Apr. 10, 2001 (hereinafter “the '767 Patent”). As the sizes of the semiconductor devices of such a multi-chip module must continue to decrease as they are positioned increasingly higher on the stack, the heights of such multi-chip modules become severely limited.

Another example of a conventional multi-chip module is described in U.S. Pat. No. 5,323,060, issued to Fogal et al. on Jun. 21, 1994 (hereinafter “the '060 Patent”). The multi-chip module of the '060 Patent includes a carrier substrate with semiconductor devices disposed thereon in a stacked arrangement. The semiconductor devices of each multi-chip module may be the same size or different sizes, with upper semiconductor devices being either smaller or larger than underlying semiconductor devices. Adjacent semiconductor devices of each of the multi-chip modules disclosed in the '060 Patent are secured to one another with an adhesive layer. The thickness of each adhesive layer well exceeds the loop heights of wire bonds protruding from a semiconductor device upon which that adhesive layer is to be positioned. Accordingly, each adhesive layer prevents the back side of an overlying, upper semiconductor device from contacting bond wires that protrude from an immediately underlying, lower semiconductor device of the multi-chip module. The adhesive layers of the multi-chip modules disclosed in the '060 Patent do not encapsulate or otherwise cover any portion of the bond wires that protrude from any of the lower semiconductor devices. It does not appear that the inventors named on the '060 Patent were concerned with overall stack heights. Thus, the multi-chip modules of the '060 Patent may be undesirably thick due to the use of thick spacers or adhesive structures between each adjacent pair of semiconductor devices.

A similar but more compact multi-chip module is disclosed in U.S. Pat. No. Re. 36,613, issued to Ball on Mar. 14, 2000 (hereinafter “the '613 Patent”). The multi-chip module of the '613 Patent includes many of the same features as those disclosed in the '060 Patent, including adhesive layers of carefully controlled thicknesses that space adjacent semiconductor devices apart a greater distance than the loop heights of wire bonds protruding from the lower of the adjacent dice. The use of thinner bond wires with low loop profile wire bonding techniques permits adjacent semiconductor devices of the multi-chip module disclosed in the '060 Patent to be positioned more closely to one another than adjacent semiconductor devices of the multi-chip modules disclosed in the '060 Patent. Nonetheless, an undesirably large amount of additional space may remain between the tops of the bond wires protruding from one semiconductor device and the back side of the next higher semiconductor device of such a multi-chip module.

Conventionally, when a particular amount of vertical spacing is needed between semiconductor devices to separate discrete conductive elements, such as bond wires, that protrude above an active surface of one semiconductor device from the back side of the next higher semiconductor device, the semiconductor devices of stacked multi-chip modules have been separated from one another with spacers. Exemplary spacers that have been used in stacked semiconductor device arrangements have been formed from dielectric coated silicon or polymide film. An adhesive material typically secures such a spacer between adjacent semiconductor devices. The use of such preformed spacers is somewhat undesirable since an additional alignment and assembly step is required for each such spacer. Proper alignment of a preformed spacer with a semiconductor device requires that the spacer not be positioned over bond pads of the semiconductor device. In addition, if a preformed spacer is placed on the surface of a semiconductor device that has already been electrically connected to a substrate, the spacer must be positioned in such a manner that the often delicate discrete conductive elements extending from the bond pads of the semiconductor device not be damaged. As those of skill in the art are aware, improper alignment and placement of such a preformed spacer may increase the likelihood that a semiconductor device may damaged, thereby decreasing overall product yields.

The distance that adjacent semiconductor devices of a stacked type multi-chip module are spaced apart from one another may be reduced by arranging the immediately underlying semiconductor devices such that upper semiconductor devices are not positioned over bond pads of or bond wires protruding therefrom. Thus, adjacent semiconductor devices may be spaced apart from one another a distance that is about the same as or less than the loop heights of the wire bonds that protrude above the active surface of the lower semiconductor device. U.S. Pat. No. 6,051,886, issued to Fogal et al. on Apr. 18, 2000 (hereinafter “the '886 Patent”) discloses such a multi-chip module. According to the '886 Patent, wire bonding is not conducted until all of the semiconductor devices of such a multi-chip module have been assembled with one another and with the underlying carrier substrate. The semiconductor devices of the multi-chip modules disclosed in the '886 Patent must have bond pads that are arranged on opposite peripheral edges. Semiconductor devices with bond pads positioned adjacent the entire peripheries thereof could not be used in the multi-chip modules of the '886 Patent. This is particularly undesirable due to the ever-increasing feature density of state-of-the-art semiconductor devices, which is often accompanied by an ever-increasing number of bond pads on semiconductor devices.

In view of the foregoing, it appears that a method for forming stacked semiconductor device assemblies which reduces the likelihood of damage to semiconductor devices would be useful, as would assemblies of stacked semiconductor devices of increased density and methods for forming such assemblies.

### SUMMARY OF THE INVENTION

The present invention includes an assembly of stacked semiconductor devices in which a first semiconductor device is secured to a substrate, such as a circuit board, interposer, another semiconductor device, or leads, and includes bond pads that are electrically connected to corresponding contact areas of the substrate by way of discrete conductive elements. A second semiconductor device of the assembly is positioned over and secured to the first semiconductor device, with the back side of the second semiconductor device resting upon, but electrically isolated from the discrete conductive elements that extend over the active surface of the first semiconductor device.

The second semiconductor device, which may be larger, smaller, or the same size as the underlying, first semiconductor device, is secured over the first semiconductor device via an adhesive material, which may comprise a dielectric material. The distance between the first semiconductor device and the second semiconductor device is determined, at least in part, by the heights the discrete conductive elements protrude over the active surface of the first semiconductor device. Thus, the heights that discrete conductive elements protrude over the active surface of the lower semiconductor device of an adjacent stacked pair of semiconductor device, along with the thicknesses of the adjacent semiconductor devices, at least partially determines the overall thickness of a package including the assembled, stacked semiconductor devices.

The discrete conductive elements that extend over the first semiconductor device may be electrically isolated from the back side of the second semiconductor device by way of a dielectric coating on at least contacting portions of one or both of the discrete conductive elements and the back side of the second semiconductor device.

In one exemplary embodiment of an assembly including stacked semiconductor devices, the adhesive may fill the entire gap between the first and second semiconductor devices, substantially encapsulating the portion of each discrete conductive element located therebetween. The adhesive material may have a low enough viscosity (high liquidity), that air or other gases or gas mixtures are readily displaced, reducing the tendency for voids to form around discrete conductive elements or between the first and second semiconductor devices.

When a low viscosity material, such as a conventional underfill material, is used to space the first and second semiconductor devices apart from one another, the first semiconductor device is secured and electrically connected to the underlying substrate by discrete conductive elements, such as bond wires. The second semiconductor device is positioned over the first semiconductor device, resting on and supported collectively by the discrete conductive elements that electrically connect bond pads of the first semiconductor device to their corresponding contact areas of the substrate. The second semiconductor device may be at least temporarily secured to the first semiconductor device by way of a small quantity of adhesive material, such as an adhesive polymer, solder flux, or the like, which may, for example, be placed on a surface of the first semiconductor device, the second semiconductor device, and/or one or more discrete conductive elements prior to positioning the second semiconductor device over the first semiconductor device. The low viscosity adhesive material may then be introduced between the first and second semiconductor devices.

The wetting properties of a low viscosity adhesive material may facilitate spreading thereof over the active surface of the first semiconductor device and the back side of the second semiconductor device, as well as capillary action, or “wicking” through the spaces between the first and second semiconductor devices and around the portions of discrete conductive elements located between the first and second semiconductor devices. Spreading of the adhesive material may be aided by application of heat thereto or by mechanical vibration of the assembly. When a fixed quantity of adhesive material that is smaller than a volume between the stacked first and second semiconductor devices (superimposed surface area times height between the devices) is used, the surface tension of the adhesive material may cause the second semiconductor device to be drawn onto the discrete conductive elements protruding above the active surface of the first semiconductor device and may also cause an even further decrease in the distance between the first and second semiconductor devices as the adhesive material spreads therebetween, thereby decreasing the overall height of the assembly. Curing of the adhesive material may cause shrinkage thereof, drawing the first and second semiconductor devices more closely to one another during curing. If the adhesive material is used to decrease the distance between the first and second semiconductor devices, it is preferred that a sufficient amount of adhesive material be used to prevent delicate, raised discrete conductive elements, such as bond wires, from bending, kinking, distorting, or collapsing onto one another.

Alternatively, or in addition, the low viscosity adhesive material may expand somewhat as it cures, pushing the backside of the second semiconductor device away from the underlying discrete conductive elements to relieve stress on the discrete conductive elements or to electrically isolate the discrete conductive elements from the back side of the second semiconductor device.

The viscosity of the adhesive material may also be sufficient to prevent the adhesive material from flowing off of the active surface of the first semiconductor device. In addition the volume of a low viscosity adhesive material may be controlled so as to prevent the adhesive material from flowing off of the active surface of the first semiconductor device.

An adhesive material that has a relatively higher viscosity may be used in another exemplary embodiment of assembly including stacked semiconductor devices. While a higher viscosity adhesive material, such as a glob-top type encapsulant compound, may not substantially fill the space between the first and second semiconductor devices or substantially encapsulate the portions of discrete conductive elements that are located between the first and second semiconductor devices, a higher viscosity adhesive material may be used to support the second semiconductor device relative to an underlying first semiconductor device prior to curing of the adhesive material.

Due to its high viscosity, such an adhesive material may be applied to a portion of the active surface of the first semiconductor device prior to positioning the second semiconductor device thereover. Optionally, a relatively high viscosity adhesive material could be applied to a surface of a second semiconductor device prior to placement thereof over the first semiconductor device. Alternatively, the second semiconductor device may be positioned over the first semiconductor device, then a high viscosity adhesive material introduced therebetween.

When a relatively high viscosity adhesive material is used, a controlled amount of force or positive loading normal to the planes of the semiconductor devices may be applied to one or both of the active surface of the second semiconductor device or the bottom of the substrate in such a manner that the first semiconductor device and second semiconductor device are biased toward one another. In this manner, the distance between the first and second semiconductor devices may be controlled so as to, for example, maintain a uniform stack height for all assemblies in a production run. Force or positive pressure may also be applied to the active surface of the second semiconductor device to facilitate spreading of a high viscosity adhesive material between the first and second semiconductor devices. If such force or positive loading is used, it is preferred that the force or positive loading not be sufficient to bend, kink, distort, or collapse delicate discrete conductive elements, such as bond wires, that electrically connect bond pads of the first semiconductor device to corresponding contact areas of the substrate.

Once the adhesive material cures, it may provide some physical support to the second semiconductor device. The presence of the adhesive material between the semiconductor devices preferably prevents delicate discrete conductive elements, such as bond wires, from being pushed onto one another, as well as the consequent electrical shorting that would result from such contact. The adhesive material may also serve as a dielectric coating for the discrete conductive elements or the back side of the second semiconductor device.

Once adhesive material that has been introduced between the first and second semiconductor devices has sufficiently cured to at least a semisolid state, bond pads of the second semiconductor device may be electrically connected to one or both of corresponding contact areas of the substrate and corresponding bond pads the first semiconductor device.

Of course, assemblies incorporating teachings of the present invention may include more than two semiconductor devices in stacked arrangement.

Once the semiconductor devices of such an assembly have been assembled with one another and electrically connected with a substrate or with one another, the assembly may be packaged, as known in the art.

Other features and advantages of the present invention will become apparent to those of ordinary skill in the art through consideration of the ensuing description, the accompanying drawings, and the appended claims.

### BRIEF DESCRIPTION OF THE DRAWINGS

In the drawings, which illustrate exemplary embodiments of various aspects of the present invention:

FIG. 1 is a schematic representation of one embodiment of an assembly incorporating teachings of the present invention;

FIGS. 2-8 are schematic representations depicting fabrication of the assembly shown in FIG. 1;

FIG. 9 is a schematic representation of a semiconductor device package including the assembly of FIG. 1;

FIG. 10 schematically depicts an assembly of the embodiment depicted in FIG. 1 that includes an additional semiconductor device;

FIG. 11 is a schematic representation of another embodiment of an assembly according to the present invention;

FIGS. 12-17 schematically depict fabrication of the assembly shown in FIG. 11; and

FIG. 18 is a schematic representation of yet another embodiment of an assembly of the present invention.

### DETAILED DESCRIPTION

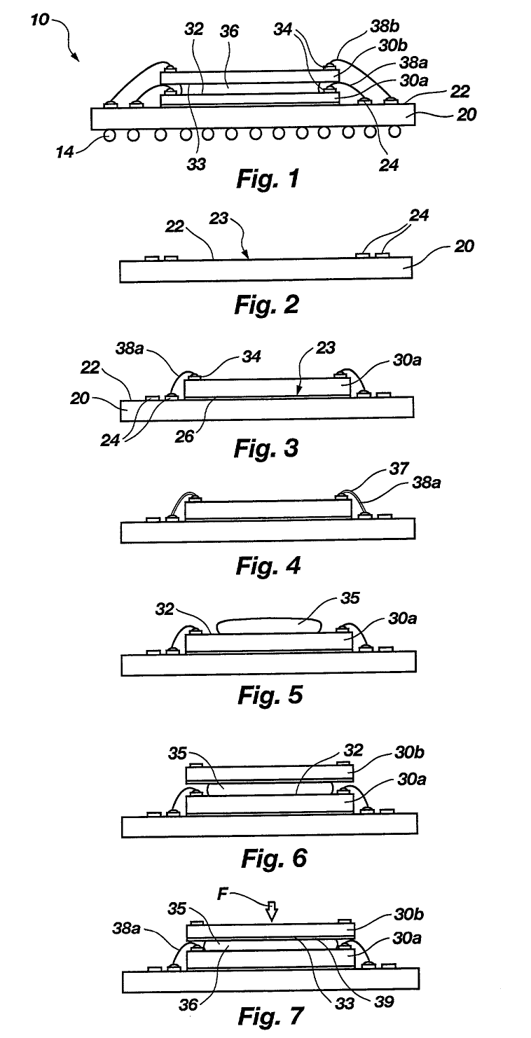

With reference to FIG. 1, an exemplary embodiment of an assembly 10 incorporating teachings of the present invention is illustrated. As shown, assembly 10 includes a substrate 20 with two semiconductor devices 30a, 30b (collectively “semiconductor devices 30”) positioned thereover in stacked arrangement. As used herein, the term “semiconductor device” includes, without limitation, singulated semiconductor dies, as well as partial wafers and wafer-scale semiconductor substrates including multiple semiconductor dice.

The depicted substrate 20 is an interposer with a number of bond pads, which are referred to herein as contact areas 24, through which electrical signals are input to or output from semiconductor devices 30 carried upon or adjacent to a surface 22 of substrate 20. Contact areas 24 correspond to bond pads 34 on an active surface 32 of one of the semiconductor devices 30 positioned upon substrate 20.

A first semiconductor device 30a is secured to substrate 20 by way of a first adhesive element 26, such as a quantity of an appropriate thermoset resin, a quantity of pressure sensitive adhesive, an adhesive-coated film or tape, or the like. Bond pads 34 of first semiconductor device 30a communicate with corresponding contact areas 24 of substrate 20 by way of discrete conductive elements 38a, such as the illustrated bond wires, tape-automated bond (TAB) elements comprising traces on a flexible dielectric film, other thermocompression bonded leads, or other known types of conductive elements.

Second semiconductor device 30b is positioned over, or “stacked” on, first semiconductor device 30a. A back side 33 of second semiconductor device 30b rests upon discrete conductive elements 38a but is electrically isolated therefrom. Second semiconductor device 30b is secured to first semiconductor device 30a by way of a second adhesive element 36 interposed between and secured to active surface 32 of first semiconductor device 30a and back side 33 of second semiconductor device 30b. By way of example only, second adhesive element 36 may comprise a thermoplastic resin, a thermoset resin, an epoxy, a silicone, a polyurethane, a parylene, or any other suitable material that, upon curing, will adhere to and substantially maintain the desired relative positions of first and second semiconductor devices 30a, 30b.

Bond pads 34 of second semiconductor device 30b are electrically connected to corresponding contact areas 24 of substrate 20 by way of discrete conductive elements 38b. As with discrete conductive elements 38a, discrete conductive elements 38b may comprise bond wires, TAB elements, other thermocompression bonded leads, or any other known type of discrete conductive element for establishing the desired communication between a bond pad 34 and its corresponding contact area 24 of a substrate 20.

Assembly 10 may also include external connective elements 14 electrically coupled to contact areas 24 by vias and, optionally, conductive traces carried by substrate 20, as known in the art. External connective elements 14 may comprise, as depicted, solder balls or conductive pins, conductive plug-in elements, conductive or conductor-filled epoxy pillars, anisotropically conductive adhesive, or any other conductive structures that are suitable for interconnecting assembly 10 with other, external electronic components.

Turning now to FIGS. 2-8, an exemplary method for fabricating assembly 10 is illustrated.

In FIG. 2, a substrate 20, in this case an interposer, is provided. Substrate 20 may be formed from silicon, glass, ceramic, an organic material (e.g., FR-4 resin), metal (e.g., copper, aluminum, etc.), or any other suitable material. Contact areas 24, shown in the form of terminal pads, are arranged on surface 22 of substrate 20 adjacent to a semiconductor device supporting region 23 of surface 22.

Next, as shown in FIG. 3, first semiconductor device 30a is positioned on and secured to supporting region 23 of surface 22 by way of first adhesive element 26. By way of example, first adhesive element 26 may comprise an adhesive coated structure, such as a polyimide film, or a quantity of adhesive material (e.g., thermoset resin, thermoplastic resin, epoxy, etc.). Discrete conductive elements 38a, depicted as bond wires, are placed between bond pads 34 of first semiconductor device 30a and their corresponding contact areas 24 of substrate 20.

FIG. 4 shows discrete conductive elements 38a as having a dielectric coating 37 on at least portions thereof Dielectric coating 37 may be formed from any suitable dielectric material, including a polymer or a dielectric oxide. When a polymer is used to form dielectric coating 37, a thin (i.e., low viscosity) liquid polymer may be applied to at least portions of discrete conductive elements 38a by a variety of suitable processes, including, without limitation, dipping discrete conductive elements 38a into a quantity of the polymer, spray coating the polymer onto discrete conductive elements 38a, and dispensing a quantity of polymer on each discrete conductive element. Alternatively, a dielectric coating 37 comprising a metal oxide may be formed on discrete conductive elements 3 8a by exposing discrete conductive elements 38a to one or more oxidizing conditions, such as increased temperature, an oxygen-species rich environment, or the like. Dielectric material, such as a silicon oxide, a silicon nitride, or a silicon oxynitride, may also be deposited onto discrete conductive elements 38 to form a dielectric coating 37 thereon. Of course, the deposition process used should be suitable for the type of dielectric material that is used to form dielectric coating 37.

FIG. 5 illustrates the application of a predetermined quantity of at least partially unconsolidated (e.g., liquid, gel, etc.) adhesive material 35 onto active surface 32 of first semiconductor device 30a. Alternatively, adhesive material 35 could be applied to a back side 33 (FIG. 6) of a second semiconductor device 30b (FIG. 6) prior to placement of second semiconductor device 30b over first semiconductor device 30a. Adhesive material 35 may have sufficient viscosity or surface tension to resist flowing off of active surface 32. As illustrated, the viscosity of adhesive material 35 may permit a quantity thereof to spread out somewhat when placed on active surface 32, while remaining relatively thick in a vertical dimension. By way of example only, adhesive material 35 may comprise a thermoplastic resin, a thermosetting resin, an epoxy, a silicone, a silicone-carbon resin, a polyimide, or a polyurethane.

As depicted in FIG. 6, second semiconductor device 30b is aligned with and positioned over first semiconductor device 30a and placed on adhesive material 35. The weight of second semiconductor device 30b, the force of a pick and place device that is used to align, position, and place second semiconductor device 30b, or a combination thereof may cause adhesive material 35 to be spread laterally over active surface 32 of first semiconductor device 30a. Adhesive material 35 may extend fully or partially between first and second semiconductor devices 30a and 30b. Once second semiconductor device 30b has been positioned over first semiconductor device 30a, adhesive material 35 may at least partially encapsulate discrete conductive elements 38a. Alternatively, discrete conductive elements 38a may contact a back side 33 of second semiconductor device 30b and be electrically isolated therefrom by other means, such as by way of a dielectric coating on portions or all of either discrete conductive elements 3 8a or back side 33.

Some nonconductive adhesive materials 35, such as those available from Dexter Corporation of Industry, Calif., as QUANTUM die attach and thermal adhesives, are thick (i.e., have high viscosities at room, or ambient temperature) while becoming thinner (i.e., less viscous) upon being heated to temperatures that are less than their curing temperatures. Thus, upon being subjected to increased temperatures, these adhesive materials 35 will draw second semiconductor device 30b toward first semiconductor device 30a. Upon reaching their cure temperatures, these materials will polymerize and maintain the spacing between first semiconductor device 30a and second semiconductor device 30b.

Additional normal force or loading, represented by arrow F, may be applied to one or both of second semiconductor device 30b, as shown in FIG. 7, and first semiconductor device 30a to bias first and second semiconductor devices 30a and 30b toward one another and to cause adhesive material 35 to spread even more. Such force or loading may be applied mechanically (e.g., with a die attach machine) or by way of one or more bursts of air or gas under positive pressure. The yield strength of the plurality of discrete conductive elements 38a diposed between first and second semiconductor devices 30a and 30b is preferably sufficient to withstand the application of biasing force oriented substantially perpendicularly relative to the planes in which the substantially mutually parallel first semiconductor device 30a and second semiconductor device 30b are located and, thus, to prevent discrete conductive elements 38a from being bent, kinked, or otherwise deformed or from collapsing onto one another.

Once regions of back side 33 of semiconductor device 30b, which are depicted in FIGS. 5-10 as being at least partially coated with dielectric material 39 (e.g., a polymer, oxide, nitride, oxynitride, etc.) to further ensure electrical isolation of second semiconductor device 30b from discrete conductive elements 3 8a, are in contact with the uppermost portions of discrete conductive elements 38a, adhesive material 35 may be cured or otherwise hardened, or permitted to cure or harden, as appropriate for the type of material used, to form second adhesive element 36. Of course, thermoplastic adhesive materials may harden upon cooling, while other types of adhesive materials 35 may be cured in a manner that depends upon the type of curable adhesive material 35 employed. By way of example only, snap curing processes, heat curing processes, UV curing processes, microwave curing processes, or any suitable combination thereof (e.g., UV curing an exposed, outer portion of adhesive material, then heat curing the interior portions thereof) may be used to cure a curable adhesive material 35.

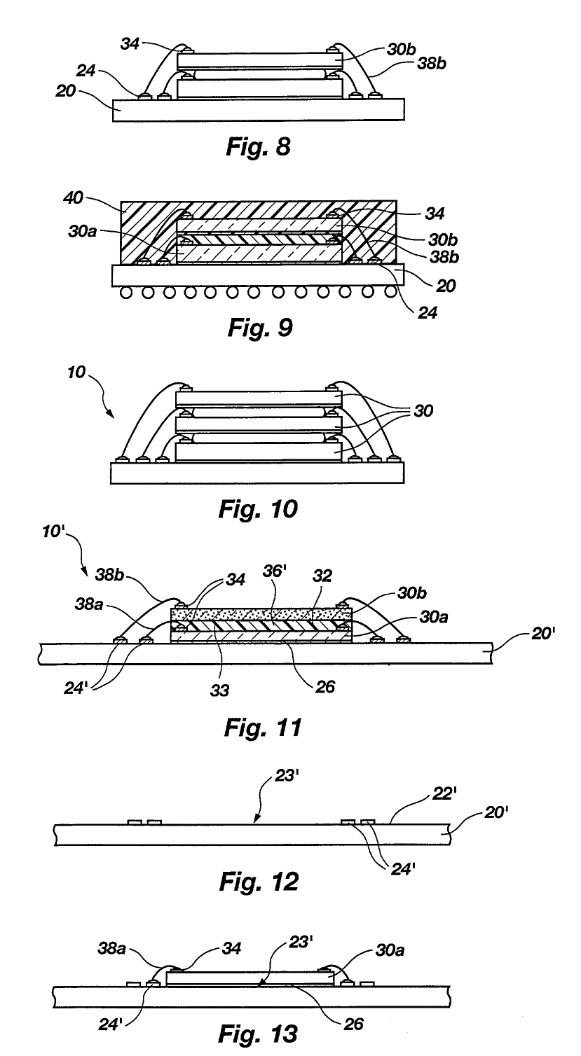

Next, as shown in FIG. 8, discrete conductive elements 38b may be positioned between bond pads 34 of second semiconductor device 30b and corresponding contact areas 24 of substrate 20 to electrically connect bond pads 34 and contact areas 24.

Once bond pads 34 of second semiconductor device 30b are in communication with their corresponding contact areas 24 of substrate 20, a protective encapsulant 40 may be placed over all or part of substrate 20, first semiconductor device 30a, and/or second semiconductor device 30b, as shown in FIG. 9. By way of example only, protective encapsulant 40 may comprise a transfer or pot molded package, as shown in FIG. 9, a stereolithographically fabricated package, or a glob top type overcoat. Of course, known materials and processes may be used to form protective encapsulant 40. In the molded package example, protective encapsulant may be formed from a transfer molding compound (e.g., a silicon particle filled thermoplastic resin), using known transfer molding processes. Pot molding may be effected, for example, using an epoxy, thermosetting resin, or polyurethane. In the sterelithography example, protective encapsulant 40 may comprise a plurality of at least partially superimposed, contiguous, mutually adhered materials layers. For example, each layer may be formed by selectively curing (e.g., with a UV laser) regions of a layer of photocurable (e.g., UV curable) material, as known in the stereolithography art. When protective encapsulant 40 is a glob top, suitable glob top materials (e.g., epoxy, silicone, silicone-carbon resin, polyimide, polyurethane, etc.) may be dispensed, as known in the art, to form protective encapsulant 40.

Optionally, as illustrated in FIG. 10, assembly 10 may include more than two semiconductor devices 30. Each additional semiconductor device may be added to assembly 10 in a similar manner to that described in reference to FIGS. 4-8.

Referring now to FIG. 11, another embodiment of assembly 10′ according to the present invention is depicted. Assembly 10′ includes a substrate 20′, in this case a circuit board, upon which a first semiconductor device 30a is positioned. First semiconductor device 30a may be secured to substrate 20′ with a first adhesive element 26, such as a quantity of an appropriate thermoset resin, a quantity of pressure sensitive adhesive, an adhesive-coated film or tape, or the like. Discrete conductive elements 38a, such as bond wires, TAB elements, or other thermocompression bonded leads, electrically connect bond pads 34 of semiconductor device 30a and corresponding contact areas 24′, in this case terminals, of substrate 20′, establishing communication between the same.

A second semiconductor device 30b is positioned over first semiconductor device 30a, with a back side 33 of second semiconductor device 30b resting upon, but electrically isolated from top portions of discrete conductive elements 38a. A second adhesive element 36′ secures back side 33 of second semiconductor device 30b to an active surface 32 of first semiconductor device 30a. As depicted, second adhesive element 36′ may substantially encapsulate portions of discrete conductive elements 38a located between first semiconductor device 30a and second semiconductor device 30b. By way of example, second adhesive element 36′ may comprise a two-stage epoxy, a thermoset resin, a silicone, an epoxy, a polyimide, or a parylene, or any other material that, upon curing, will substantially maintain the distance between active surface 32 of first semiconductor device 30a and back side 33 of second semiconductor device 30b.

Discrete conductive elements 38b electrically connect bond pads 34 of second semiconductor device 30b and their corresponding contact areas 24′ of substrate 20′. Again, bond wires, TAB elements, other thermocompression bonded leads, or the like may be used as discrete conductive elements 38b.

An example of the formation of assembly 10′ is shown in FIGS. 12-17.

In FIG. 12, a substrate 20′ is provided. Substrate 20′ includes a semiconductor device supporting region 23′ on a surface 22′ thereof and contact areas 24′ exposed to surface 22′ and positioned proximate to supporting region 23′. At least some of contact areas 24′ correspond to bond pads 34 (FIG. 11) of a semiconductor device 30a, 30b to be positioned over substrate 20′.

FIG. 13 shows a first semiconductor device 30a being positioned over supporting region 23′ and secured thereto with a first adhesive element 26. In addition, FIG. 13 depicts the electrical connection of bond pads 34 of first semiconductor device 30a to corresponding contact areas 24′ of substrate 20′ by way of discrete conductive elements 38a.

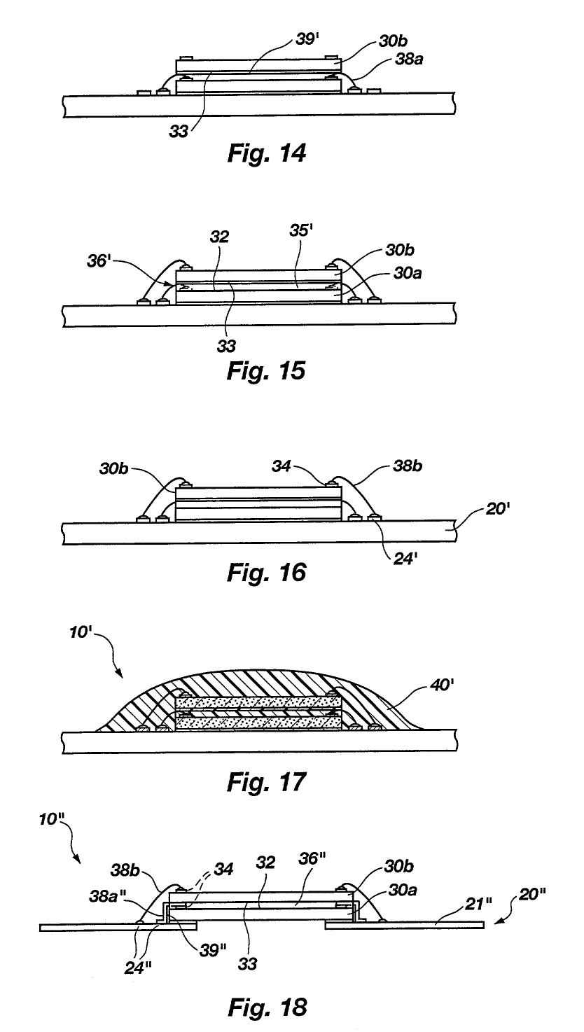

Second semiconductor device 30b is positioned on the uppermost portions of discrete conductive elements 38a, as shown in FIG. 14. Second semiconductor device 30b and discrete conductive elements 38a contacting back side 33 thereof may be electrically isolated from one another by way of dielectric coatings 37 on at least portions of discrete conductive elements 38a, as depicted in FIG. 4, or by way of a dielectric layer 39′ on at least portions of back side 33 of second semiconductor device 30b that will contact discrete conductive elements 38a.

Referring now to FIG. 15, a predetermined quantity of at least partially unconsolidated (i.e., liquid, gel, etc.) adhesive material 35′ may be introduced between active surface 32 of first semiconductor device 30a and back side 33 of second semiconductor device 30b. The viscosity of adhesive material 35′ preferably permits adhesive material 35′ to wick, or flow between, active surface 32 and back side 33 by capillary action. Accordingly, known underfill materials (e.g., thermoset resins, two-stage epoxies, etc.) are examples of materials that are suitable for use as adhesive material 35′. Upon hardening or curing, adhesive material 35′ forms second adhesive element 36′.

Adhesive material 35′ may be cured or otherwise hardened by an appropriate process or combination of processes, depending, of course, on the type of adhesive material 35′ employed. By way of example only, snap curing processes, heat curing processes, UV curing processes, microwave curing processes, or any appropriate combination thereof may be used.

Once adhesive material 35′ has sufficiently cured or hardened, known processes may be employed to place discrete conductive elements 38b, such as bond wires, TAB elements, or other thermocompression bonded leads, between bond pads 34 of second semiconductor device 30b and corresponding contact areas 24′ of substrate 20′, as illustrated in FIG. 16.

As shown in FIG. 17, at least portions of assembly 10′ may be encapsulated, or packaged, as known in the art. By way of example, a protective encapsulant 40′ may be formed by glob top encapsulation techniques employing suitable glob top encapsulant materials. Alternatively, other packaging techniques, including, without limitation, transfer molding, pot molding, and stereolithography, may be employed.

Turning now to FIG. 18, another exemplary embodiment of assembly 10″ of the present invention is illustrated. Assembly 10″ includes a substrate 20″ in the form of leads 21 ″, a first semiconductor device 30a with which leads 21 ″ of substrate 20″ are associated, and discrete conductive elements 38a″, in the form of TAB elements, electrically connecting bond pads 34 of first semiconductor device 30a and corresponding contact areas 24″ on leads 21″. Discrete conductive elements 38a″ are electrically isolated from first semiconductor device 30a by way of a dielectric film 39″ therebetween, such as a thin layer of a dielectric polymer (e.g., polyimide), silicon oxide, silicon nitride, or silicon oxynitride, which may be formed by known processes.

Assembly 10″ also includes a second semiconductor device 30b positioned upon portions of discrete conductive elements 38a″ in electrical isolation therefrom, as well as an adhesive element 36″ positioned between an active surface 32 of first semiconductor device 30a and a back side 33 of second semiconductor device 30b. Bond pads 34 of second semiconductor device 30b communicate with corresponding contact areas 24″ of substrate 20″ by way of discrete conductive elements 38b, which are depicted as being bond wires, positioned therebetween.

As another alternative, an assembly incorporating teachings of the present invention may include a substrate which comprises leads-over-chip (LOC) type leads, which extend over a portion of an active surface of at least one stacked semiconductor device upon which at least one other semiconductor device is stacked.

Although the foregoing description contains many specifics, these should not be construed as limiting the scope of the present invention, but merely as providing illustrations of some exemplary embodiments. Similarly, other embodiments of the invention may be devised which do not depart from the spirit or scope of the present invention. Features from different embodiments may be employed in combination. The scope of the invention is, therefore, indicated and limited only by the appended claims and their legal equivalents, rather than by the foregoing description. All additions, deletions, and modifications to the invention, as disclosed herein, which fall within the meaning and scope of the claims are to be embraced thereby.

What is claimed is:

1. A semiconductor device assembly, comprising:
a first semiconductor device;
discrete conductive elements extending over portions of an active surface of said first semiconductor device; and
a second semiconductor device positioned at least partially over said first semiconductor device and resting upon said discrete conductive elements in electrical isolation therefrom.

2. The semiconductor device assembly of claim 1, further comprising a substrate to which said first semiconductor device is secured.

3. The semiconductor device assembly of claim 2, wherein said substrate comprises at least one of a circuit board, an interposer, another semiconductor device, and leads.

4. The semiconductor device assembly of claim 1, wherein said discrete conductive elements comprise at least one of bond wires, tape-automated bond elements, and thermocompression bonded leads.

5. The semiconductor device assembly of claim 1, further comprising:
a dielectric coating on at least portions of said discrete conductive elements and electrically isolating at least said portions of said discrete conductive elements from a back side of said second semiconductor device.

6. The semiconductor device assembly of claim 5, wherein said dielectric coating comprises at least one of a nonconductive oxide and a polymer.

7. The semiconductor device assembly of claim 1, further comprising:
a dielectric coating on at least portions of a back side of said second semiconductor device and electrically isolating said second semiconductor device from at least portions of discrete conductive elements adjacent thereto.

8. The semiconductor device assembly of claim 7, wherein said dielectric coating comprises at least one of a nonconductive oxide and a nonconductive polymer.

9. The semiconductor device assembly of claim 1, further comprising: an adhesive element between said first and second semiconductor devices.

10. The semiconductor device assembly of claim 9, wherein said adhesive element substantially encapsulates at least portions of said discrete conductive elements located between said first and second semiconductor devices.

11. The semiconductor device assembly of claim 1, further comprising:
at least one additional semiconductor device positioned over said second semiconductor device.

12. The semiconductor device assembly of claim 1, further comprising:
encapsulant material covering at least a portion of at least one of said second semiconductor device, said first semiconductor device, and said substrate.

13. A multi-chip module, comprising:
a substrate including contact areas;
a first semiconductor device comprising bond pads in communication with corresponding contact areas of said substrate by way of discrete conductive elements extending therebetween; and
at least one second semiconductor device positioned at least partially over said first semiconductor device, a back side of said at least a second semiconductor device contacting and electrically isolated from said discrete conductive elements.

14. The multi-chip module of claim 13, further comprising:
an adhesive element positioned between said first semiconductor device and said at least a second semiconductor device.

15. The multi-chip module of claim 14, wherein said adhesive element substantially laterally surrounds at least portions of said discrete conductive elements located between said first semiconductor device and said second semiconductor device.

16. The multi-chip module of claim 13, further comprising:
a dielectric coating on at least portions of said discrete conductive elements in contact with said backside of said at least one second semiconductor device.

17. The multi-chip module of claim 13, further comprising:
a dielectric coating on at least portions of said back side of said at least one second semiconductor device in contact with said discrete conductive elements.

18. The multi-chip module of claim 13, wherein said substrate comprises at least one of a circuit board, an interposer, another semiconductor device, and leads.

19. The multi-chip module of claim 13, wherein said discrete conductive elements comprise at least one of bond wires, tape-automated bond elements, and thermocompression bonded leads.

20. The multi-chip module of claim 13, wherein each of said discrete conductive elements comprises a lead.

21. The multi-chip module of claim 13, further comprising:
an encapsulant material surrounding at least portions of said first semiconductor device and said at least a second semiconductor device.

22. The multi-chip module of claim 13, further comprising:
external connective elements on said substrate coupled to said contact areas.

23. A method for assembling semiconductor devices, comprising:
providing a first semiconductor device;
placing discrete conductive elements over portions of said first semiconductor device; and
positioning a second semiconductor device at least partially over said first semiconductor device and contacting at least some of said discrete conductive elements with a backside of said second semiconductor device.

24. The method of claim 23, wherein said positioning said second semiconductor device comprises positioning said second semiconductor device on said at least some of said discrete conductive elements with said back side and said discrete conductive elements in mutual electrical isolation.

25. The method of claim 24, further comprising:
providing a dielectric coating on at least portions of said discrete conductive elements.

26. The method of claim 25, wherein said providing comprises forming at least one of a dielectric oxide and a dielectric polymer coating on at least said portions of said discrete conductive elements.

27. The method of claim 24, further comprising:
forming a dielectric layer on at least portions of said back side.

28. The method of claim 27, wherein said forming is effected prior to said positioning said second semiconductor device.

29. The method of claim 23, further comprising:
applying a quantity of adhesive material to at least an active surface of said first semiconductor device.

30. The method of claim 29, further comprising:
drawing said second semiconductor device toward said first semiconductor device.

31. The method of claim 30, wherein said drawing is effected by at least one of capillary action of said adhesive material, curing of said adhesive material, application of heat to said adhesive material, and vibration of said adhesive material.

32. The method of claim 29, wherein said applying includes applying said quantity of adhesive material to said back side of said second semiconductor device.

33. The method of claim 29, wherein said applying is effected after said positioning said second semiconductor device.

34. The method of claim 33, further comprising:
drawing said second semiconductor device toward said first semiconductor device.

35. The method of claim 34, wherein said drawing is effected during curing of said adhesive material.

36. The method of claim 29, wherein said applying is effected before said positioning said second semiconductor device.

37. The method of claim 36, further comprising:
biasing at least one of said first and second semiconductor devices toward the other of said first and second semiconductor devices.

38. The method of claim 37, further comprising:
controlling said biasing.

39. The method of claim 38, wherein said controlling said biasing comprises controlling biasing force to a level insufficient to deform, kink, bend, or collapse said discrete conductive elements.

40. The method of claim 23, further comprising:
securing said first semiconductor device and a substrate to one another.

41. The method of claim 40, wherein said placing said discrete conductive elements comprises securing said discrete conductive elements to contact areas of said substrate and bond pads of said first semiconductor device.

42. The method of claim 41, wherein said securing comprises electrically connecting bond pads of said second semiconductor device to corresponding contact areas of said substrate.

43. The method of claim 42, further comprising:
encapsulating at least a portion of at least one of said substrate, said first semiconductor device, and said second semiconductor device.

44. The method of claim 42, further comprising:
forming external conductive elements on said substrate in electrical communication with corresponding contact areas.

45. A method for assembling semiconductor devices in a stacked arrangement with the stacked arrangement having a height substantially equal to combined thicknesses of each of the semiconductor devices and distances discrete conductive elements associated therewith protrude above each semiconductor device, comprising:
providing a first semiconductor device with discrete conductive elements protruding from an active surface thereof, and
positioning a second semiconductor device at least partially over said first semiconductor device and on at least some of said discrete conductive elements.

46. The method of claim 45, wherein said positioning comprises positioning said second semiconductor device on said at least some of said discrete conductive elements with a back side of said second semiconductor device electrically isolated from said discrete conductive elements.

47. The method of claim 46, further comprising:
providing a dielectric coating on at least portions of said at least some of said discrete conductive elements.

48. The method of claim 46, further comprising:
forming a dielectric coating on at least portions of said back side.

49. The method of claim 45, further comprising:
applying a quantity of adhesive material at least to said active surface of said first semiconductor device.

50. The method of claim 49, further comprising:
drawing said second semiconductor device toward said first semiconductor device.

51. The method of claim 50, wherein said drawing is effected by at least one of capillary action of said adhesive material, curing of said adhesive material, application of heat to said adhesive material, and vibration of said adhesive material.

52. The method of claim 49, wherein said applying is effected before said positioning.

53. The method of claim 49, wherein said applying is effected after said positioning.

54. The method of claim 53, further comprising:
drawing said second semiconductor device toward said first semiconductor device.

55. The method of claim 54, wherein said drawing is effected during curing of said adhesive material.

56. The method of claim 49, further comprising:
biasing at least one of said first and second semiconductor devices toward the other of said first and second semiconductor devices.

57. The method of claim 56, further comprising:
controlling said biasing.

58. The method of claim 57, wherein said controlling said biasing comprises controlling biasing force to a level insufficient to deform, kink, bend, or collapse said discrete conductive elements.

59. The method of claim 45, further comprising:
positioning said first semiconductor device relative to a substrate.

60. The method of claim 59, further comprising:
connecting said discrete conductive elements to corresponding contact areas of said substrate.

61. The method of claim 59, further comprising:
establishing electrical communication between bond pads of said second semiconductor device and corresponding contact areas of said substrate.

62. The method of claim 61, wherein said establishing communication comprises:
placing additional discrete conductive elements between each of said bond pads and a corresponding contact area of said corresponding contact areas.

63. The method of claim 46, further comprising:
providing at least one external connective element in communication with at least one bond pad of each of said first and second semiconductor devices.

64. The method of claim 63, further comprising:
encapsulating at least portions of said first and second semiconductor devices.

65. A semiconductor device assembly, comprising at least two semiconductor devices in a stacked arrangement, said stacked arrangement having a height substantially equal to combined thicknesses of said at least two semiconductor devices and distances discrete conductive elements associated therewith protrude above each semiconductor device of said at least two semiconductor devices.

66. The semiconductor device assembly of claim 65, wherein said discrete conductive elements comprise bond wires.

67. The semiconductor device assembly of claim 65, wherein a back side of each upper semiconductor device of said at least two semiconductor devices rests upon upper portions of discrete conductive elements protruding above a surface of a next lower semiconductor device of said at least two semiconductor devices.

68. The semiconductor device assembly of claim 65, further comprising:
a substrate to which at least one semiconductor device of said at least two semiconductor devices is secured, said height of said stacked arrangement including a thickness of said substrate.

69. The semiconductor device assembly of claim 35, further comprising:
a protective encapsulant surrounding portions of at least one of said at least two semiconductor devices, said height of said stacked arrangement including a thickness of said protective encapsulant over a surface of at least one of said at least two semiconductor devices.
